(19) United States
(12) Patent Application Publication
(10) Pub. No.: US 2008/0237604 A1
(43) Pub. Date: Oct. 2, 2008

(54) PLASMA NITRIDED GATE OXIDE, HIGH-K METAL GATE BASED CMOS DEVICE

(76) Inventors: Husam Niman Alshareef, Plano, TX (US); Manuel Quevedo-Lopez, Richardson, TX (US)

Correspondence Address: TEXAS INSTRUMENTS INCORPORATED, P O BOX 655474, M/S 3999, DALLAS, TX, 75265, US

(21) Appl. No.: 11/694,419

(22) Filed: Mar. 30, 2007

(51) Int. Cl. H01L 27/108; H01L 21/8238

(52) U.S. Cl. 257/69; 438/216; 257/E27.084; 257/E21.632

(57) ABSTRACT

In accordance with the invention, there are CMOS devices and semiconductor devices and methods of fabricating them. The CMOS device can include a substrate including a first active region and a second active region and a first transistor device over the first active region, wherein the first transistor device includes a high-K layer over the first active region, a first dielectric capping layer on the high-K layer, and a first metal gate layer over the first dielectric capping layer. The CMOS device can also include a second transistor device over the second active region, wherein the second transistor device includes a high-K layer over the second active region, a second dielectric capping layer on the second high-K layer, and a second metal gate layer over the second dielectric capping layer.

### FIELD OF THE INVENTION

The subject matter of this invention relates to methods of fabricating semiconductor devices. More particularly, the subject matter of this invention relates to devices and methods of fabricating plasma nitrided gate oxide, high-k metal gate based devices.

### BACKGROUND OF THE INVENTION

With the decrease in the size of transistors, the thickness of the silicon oxide gate dielectric has become only a few atomic layers thick, resulting in tunneling current leakage and an increase in the power dissipation and heat. Thus, there is a need to use high-k gate dielectrics with a lower equivalent oxide thickness (EOT) for better performance. The use of high-k gate dielectrics also requires metal gates that can replace polysilicon gates. Hafnium based gate dielectrics have demonstrated transistor characteristics and mobilities as good as those of silicon oxynitride gate dielectrics. However, it has been difficult with hafnium based dielectrics to obtain work functions near the silicon band edges (4.0 eV and 5.1 eV). These band edge work functions are needed if metal gates are to replace polysilicon electrodes.

Thus, there is a need to overcome these and other problems of the prior art and to provide methods of fabricating semiconductor devices including dielectrics with work functions near the silicon band edges.

### SUMMARY OF THE INVENTION

In accordance with the present teachings, there is a method of making a CMOS device. The method can include providing a substrate including a first active region and a second active region and forming a high-K layer over the first active region and the second active region. The method can also include forming a first dielectric capping layer disposed on the high-K layer over the first active region, forming a second dielectric capping layer disposed on the high-K layer over the second active region, and forming a metal gate layer over the first dielectric capping layer and the second dielectric capping layer. The method can further include patterning the high-K layer, the first and the second dielectric capping layers and the metal gate layer to form a first transistor device over the first active region and a second transistor device over the second active region.

According to various embodiments of the present teachings, there is a method of making an integrated circuit. The method can include providing a substrate including a first active region and a second active region and forming a high-K layer over the first active region and the second active region. The method can also include forming a first dielectric capping layer on the high-K layer over the first active region and forming a metal gate on the first dielectric capping layer over the first active region and on the high-K layer over the second active region. The method can further include patterning the high-K layer, the first dielectric capping layer, and the metal gate layer to form a first transistor device over the first active region and patterning the high-K layer and the metal gate layer to form a second transistor device over the second active region.

According to another embodiment of the present teachings, there is a semiconductor device. The semiconductor device can include a substrate including a first active region and a second active region. The semiconductor device can also include a first transistor device over the first active region, wherein the first transistor device includes a high-K layer over the first active region, a first dielectric capping layer on the high-K layer, and a first metal gate layer on the first dielectric capping layer. The semiconductor device can further include a second transistor device over the second active region, wherein the second transistor device includes a high-K layer over the second active region and a second metal gate layer on the high-K layer.

According to yet another embodiment of the present teachings, there is a CMOS device including a substrate including a first active region and a second active region. The CMOS device can also include a first transistor device over the first active region, wherein the first transistor device includes a high-K layer over the first active region, a first dielectric capping layer disposed on the high-K layer, and a first metal gate layer over the first dielectric capping layer. The CMOS device can further include a second transistor device over the second active region, wherein the second transistor device includes a high-K layer over the second active region, a second dielectric capping layer disposed on the second high-K layer, and a second metal gate layer over the second dielectric capping layer.

Additional advantages of the embodiments will be set forth in part in the description which follows, and in part will be obvious from the description, or may be learned by practice of the invention. The advantages will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate embodiments of the invention and together with the description, serve to explain the principles of the invention.

### BRIEF DESCRIPTION OF THE DRAWINGS

FIGS. 1A-1K illustrate a method of making a CMOS device in accordance with various embodiments of the present teachings.

FIGS. 2A-2I depict a method of making an integrated circuit according to various embodiments of the present teachings.

### DESCRIPTION OF THE EMBODIMENTS

Reference will now be made in detail to the exemplary embodiments, examples of which are illustrated in the accompanying drawings. Wherever possible, the same reference numbers will be used throughout the drawings to refer to the same or like parts.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less that 10” can assume negative values, e.g. −1, −2, −3, −10, −20, −30, etc.

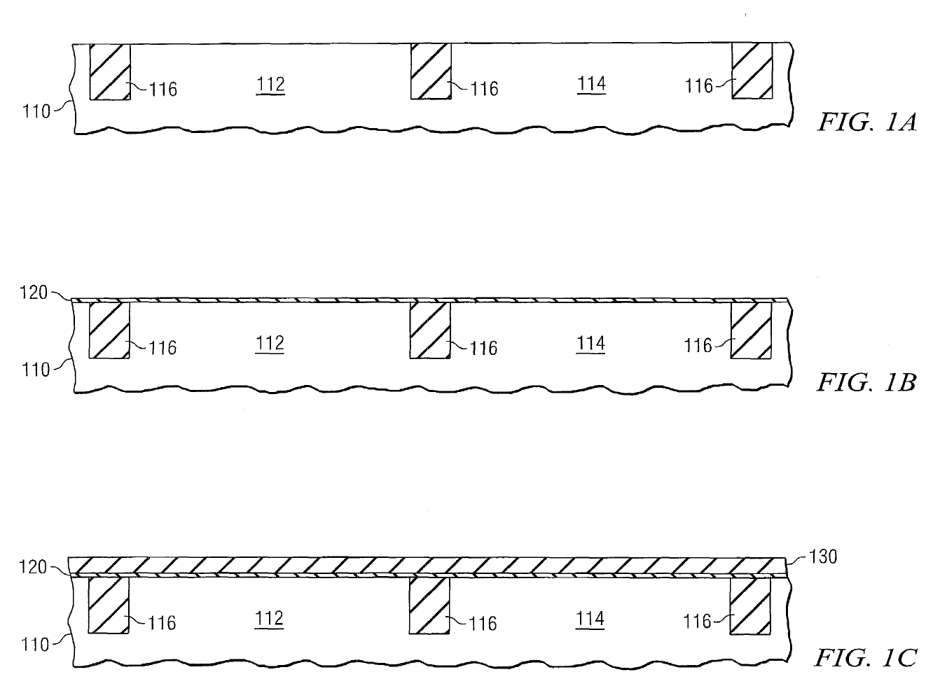

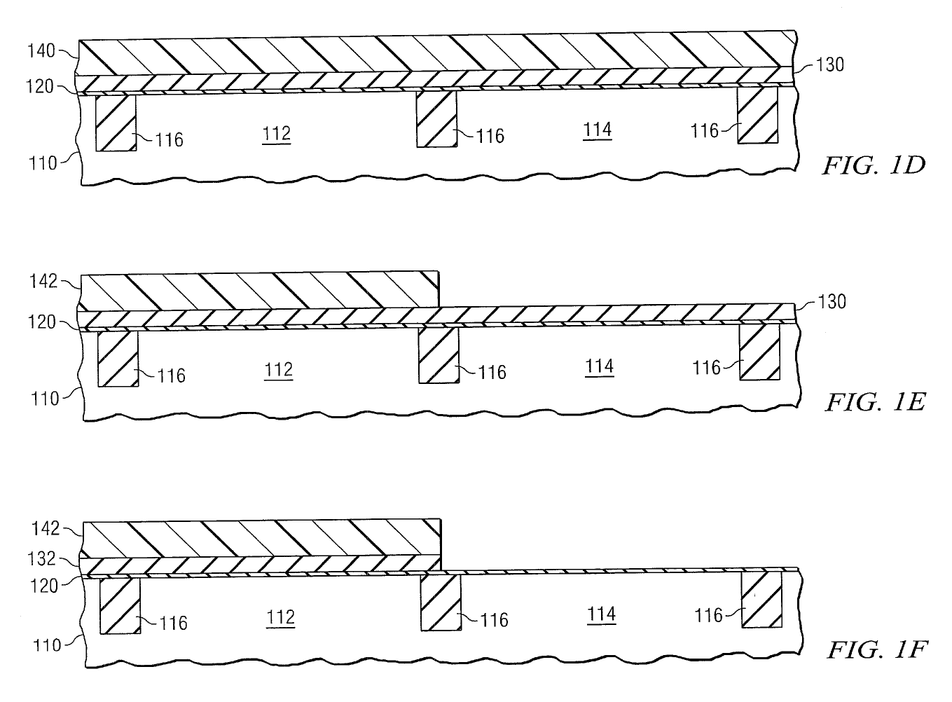

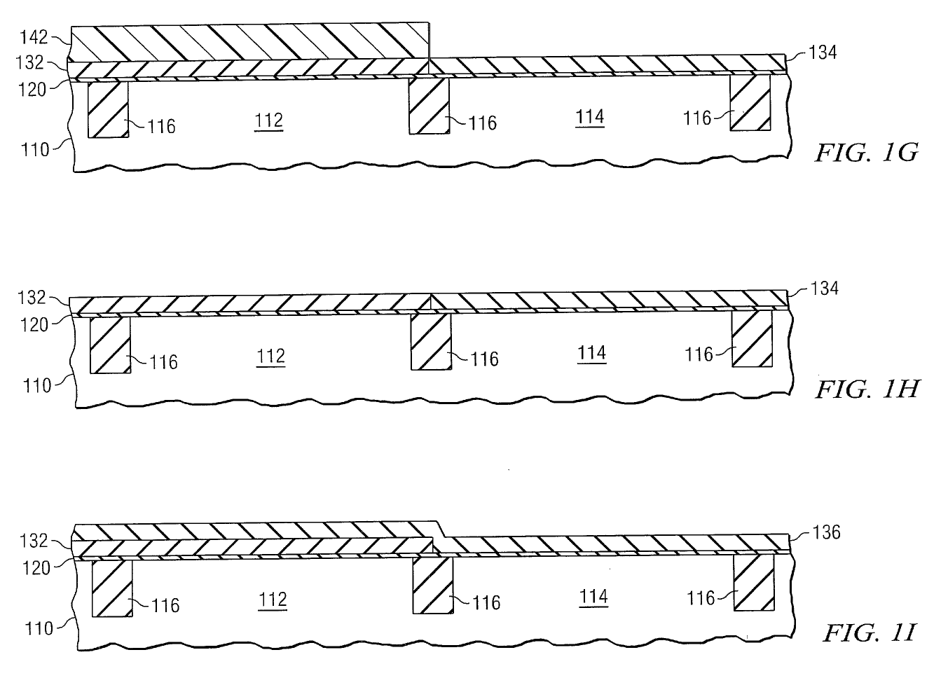

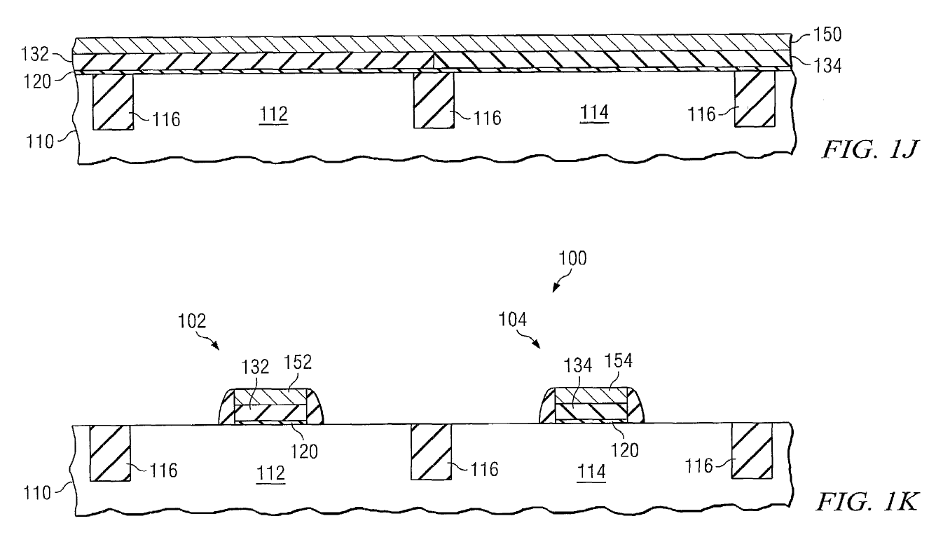

FIGS. 1A-1K illustrate a method of making a CMOS device 100 according to various embodiments of the present teachings. The method of making the CMOS device 100 can include providing a substrate 110 including a first active region 112, a second active region 114, and a trench isolation region 116, as shown in FIG. 1A. In some embodiments, the substrate 110 can include a semiconductor material, such as silicon or polysilicon. In other embodiments, the substrate 110 can include materials such as gallium arsenide, germanium, silicon-germanium, epitaxial formations, silicon carbide, indium phosphide, silicon-on-insulator (SOI), strained Si substrates, and/or any other substrate materials that can be employed for fabricating integrated circuits. The trench isolation region 116 can be formed by any suitable method, such as, for example, by etching (e.g. reactive ion etching) trenches selectively, filling the trenches with a dielectric fill material, such as tetraethylorthosilicate (TEOS), and planarizing. In some embodiments, trench isolation region 116 can be formed by local oxidation of silicon (LOCOS).

As shown in FIG. 1B, the method of making a CMOS device 100 can further include forming a high-K layer 120 over the first active region 112 and the second active region 114. Any suitable high-K layer 120 can be formed over the first active region 112 and the second active region 114. However, in some embodiments, forming a high-K layer 120 over the first active region 112 and the second active region 114 can include forming one or more of a silicon oxide layer, plasma nitrided oxide layer, a hafnium based dielectric layer, and a zirconium based dielectric layer. The hafnium and zirconium based dielectric layer can be formed by any suitable method including, but not limited to chemical vapor deposition (CVD), atomic layer deposition (ALD), physical vapor deposition (PVD), and chemical bath deposition (CBD). The plasma nitrided oxide layer can be formed by any suitable method, such as by plasma nitridation process including applying a nitrogen-containing gas, such as N₂, N₂O, NO, and NH₃ or a mixture of nitrogen-containing gas and inert gases, such as He, Ne, Ar, Kr, and Xe to an exposed surface of the oxide layer using a plasma nitridation system (Applied Materials Inc., Santa Clara, Calif.). The plasma nitridation process can be carried out for about 3 seconds to about 60 seconds at a power of about 2 watts to about 2000 watts at a pressure of about 5 mtorr to about 50 Torr.

The method of making a CMOS device 100 can also include forming a first dielectric capping layer 132 disposed on the high-K layer 120 over the first active region 112, as shown in FIG. 1F. The first dielectric capping layer 132 can include an aluminum-containing dielectric such as aluminum nitride, aluminum oxide, and aluminum oxynitride layer. The method of forming a first dielectric capping layer 132 over the first active region 112 can include depositing a first dielectric capping layer 130 over the first active region 112 and the second active region 114 as shown in FIG. 1C, depositing a layer of photoresist 140 over the first dielectric capping layer 130 as shown in FIG. 1D, and patterning the photoresist layer 140 by lithography to form a patterned photoresist layer 142 over the first active region 114, as shown in FIG. 1E. The first dielectric capping layer 130 can be deposited using techniques such as, but not limited to physical vapor deposition (PVD), atomic layer deposition (ALD), chemical vapor deposition (CVD), and molecular beam epitaxy (MBE). The method of forming a first dielectric capping layer 132 over the first active region 112 can further include using the patterned photoresist layer 142 as a mask and selectively etching the first dielectric capping layer 130 from over the second active region 114 as shown in FIG. 1F. In various embodiments, etching can include but is not limited to chemical etching, plasma etching, reactive ion etching, wet etching, physical (ion milling) etching, and combinations thereof. In various embodiments, the etch process can be highly anisotropic and can give vertical sidewalls to the patterned features.

Referring to FIG. 1G, the method of making a CMOS device 100 can also include forming a second dielectric capping layer 134 disposed on the high-K layer 120 over the second active region 114. The second dielectric capping layer 134 can include an oxide layer selected from the group consisting of lanthanum oxide, yttrium oxide, gadolinium oxide, cerium oxide, dysprosium oxide, ytterbium oxide, terbium oxide, erbium oxide, and scandium oxide. The method can further include removing the photoresist layer 142, as shown in FIG. 1H and forming a metal gate layer 150 over the first dielectric capping layer and the second dielectric capping layer, as shown in FIG. 1J. The metal gate layer 150 can include midgap metal gate materials including, but not limited to tantalum nitride, zirconium nitride, and titanium nitride. In some embodiments, a second dielectric capping layer 136 can be deposited on the first dielectric capping layer 132 over the first active region 112 and on the high-K layer 120 over the second active region 114, as shown in FIG. 1I. The second dielectric capping layer 134, 136 and the metal gate layer 150 can be deposited using techniques such as, but not limited to physical vapor deposition (PVD), atomic layer deposition (ALD), chemical vapor deposition (CVD), and molecular beam epitaxy (MBE). The method of making a CMOS device 100 can further include patterning the high-K layer 120, the first and the second dielectric capping layers 132, 134, and the metal gate layer 150 to form a first transistor device 102 over the first active region 112 and a second transistor device 104 over the second active region 114, as shown in FIG. 1K. In various embodiments, metal gate layers 152 and 154 can be formed when the metal gate layer 150 is patterned.

In various embodiments, the high-K layer 120 can have a thickness from about 10 Å to about 50 Å, the first dielectric capping layer 132 can have a thickness from about 1 Å to about 20 Å, the second dielectric capping layer 134, 136 can have a thickness from about 1 Å to about 20 Å, and the metal gate layer 150 can have a thickness from about 20 Å to about 200 Å.

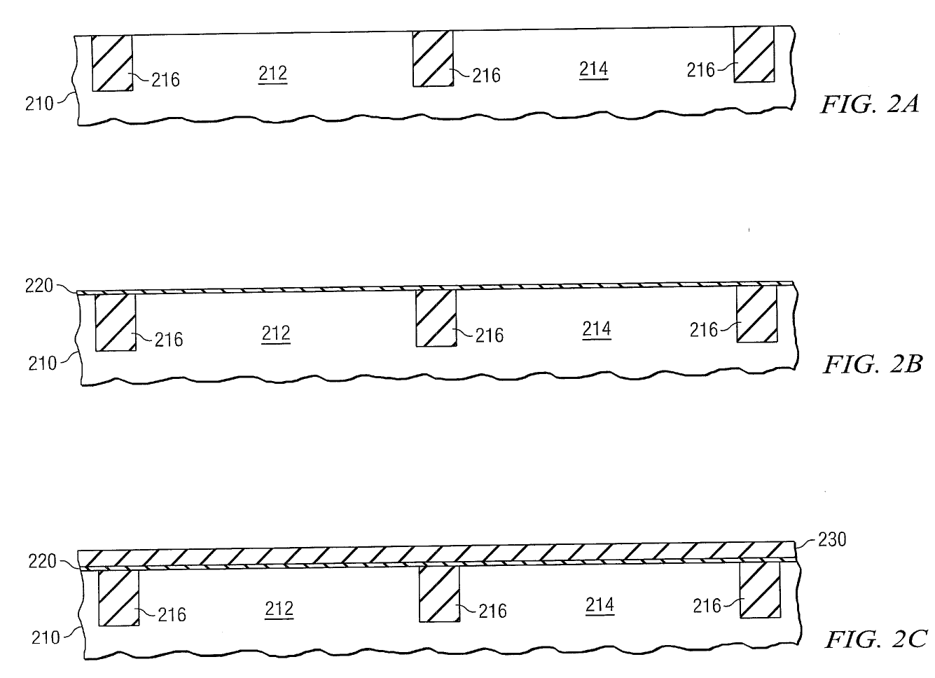

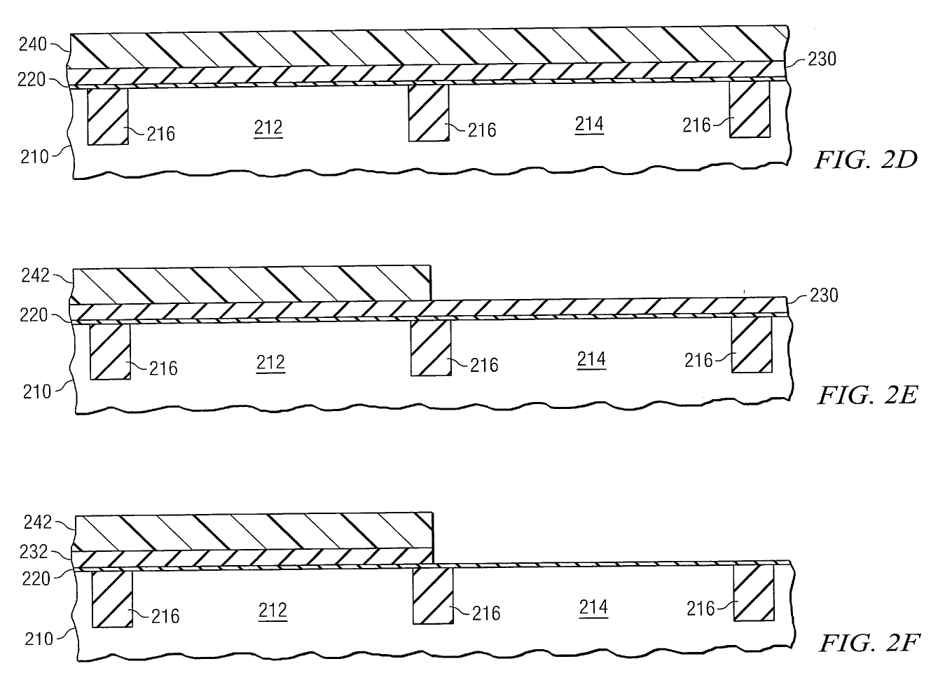

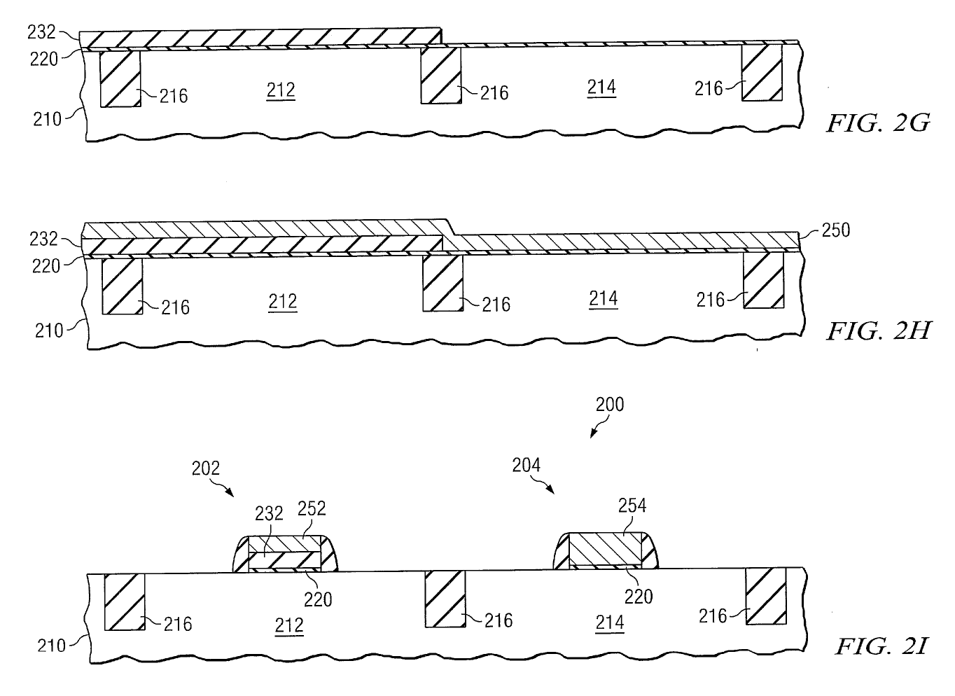

FIGS. 2A-2I illustrate a method of making an integrated circuit including one or more semiconductor devices 200 according to various embodiments of the present teachings. The method of making the integrated circuit an include providing a semiconductor substrate 210 including a first active region 212, a second active region 214, and a trench isolation region 216, as shown in FIG. 2A. The method can also include forming a high-K layer 220 over the first active region 212 and the second active region 214, as shown in FIG. 2B. The high-K layer 220 can include any suitable high-K dielectric material, such as one or more of a silicon oxide layer, a plasma nitrided oxide layer, a hafnium based dielectric layer, and a zirconium based dielectric layer. In various embodiments, the high-K layer 220 can have a thickness from about 10 Å to about 40 Å. Referring to FIG. 2G, the method can include forming a first dielectric capping layer 232 on the high-K layer 220 over the first active region 212. In some embodiments, the first dielectric capping layer 232 can include an aluminum-containing dielectric such as aluminum nitride, aluminum oxide, and aluminum oxynitride layer. In other embodiments, the first dielectric capping layer 232 can include an oxide layer selected from the group consisting of lanthanum oxide, yttrium oxide, gadolinium oxide, cerium oxide, dysprosium oxide, ytterbium oxide, terbium oxide, erbium oxide, and scandium oxide. In some other embodiments, the first dielectric capping layer 232 can have a thickness from about 10 Å to about 40 Å. The method of forming a first dielectric capping layer 232 on the high-K layer 220 over the first active region 212 can include depositing a first dielectric capping layer 230 over the first active region 212 and the second active region 214 and patterning the first dielectric capping layer 230 by a lithographic process, as shown in FIGS. 2C-2F. For example, a radiation sensitive coating such as, for example, a photoresist (“resist”) 240 can be formed over the first dielectric capping layer 230. The resist 240 can then be patterned by selective exposure through a mask. The exposed areas of the resist 240 can become either more or less soluble than the unexposed areas depending on the type of the resist 240 used. A solvent developer can be used to remove the soluble resist thereby leaving the pattern resist 242 over the first active region 212 as shown in FIG. 2E. The first dielectric capping layer 230 can then be etched from the second active region 214, as shown in FIG. 2F. The etching process can include, but is not limited to, chemical etching, plasma etching, reactive ion etching, wet etching, physical (ion milling) etching, and combinations thereof. The method of making an integrated circuit can further include forming a metal gate layer 250 on the first dielectric capping layer 232 over the first active region 212 and on the high-K layer 220 over the second active region 214, as shown in FIG. 2H. A patterning process can then be carried out to form a first transistor device 202 over the first active region 212 and a second transistor device 204 over the second active region 214, as shown in FIG. 2I. The metal gate layer 250, and the patterned metal gates 252 and 254 formed therefrom, can include a high work function metal gate selected from the group consisting of tantalum cabonitride, tungsten, tungsten nitride, molybdenum nitride, ruthenium, and ruthenium oxide. In various embodiments, the metal gate layer 250 and the patterned metal gates 252 and 254 can have a thickness from about 20 Å to about 100 Å.

According to various embodiments of the present teachings, there is a semiconductor device 200 as shown in FIG. 2I. The semiconductor device 200 can include a substrate 210 including a first active region 212, a second active region 214, and a trench isolation region 216. The semiconductor device can also include a first transistor device 202 over the first active region 212, and a second transistor device 204 over the second active region 214. In some embodiments, the first transistor device 202 can include a high-K layer 220 over the first active region 212, a first dielectric capping layer 232 on the high-K layer 220, and a first metal gate layer 252 on the first dielectric capping layer 232. In other embodiments, the second transistor device 204 can include a high-K layer 220 over the second active region 214 and a second metal gate layer 254 on the high-K layer 220.

In various embodiments, the high-K layer 220 can include any suitable high-K material, such as one or more of a silicon oxide layer, a plasma nitrided oxide layer, a hafnium based dielectric layer, and a zirconium based dielectric layer. In some embodiments, the first dielectric capping layer 232 can include an aluminum-containing dielectric such as aluminum nitride, aluminum oxide, and aluminum oxynitride layer; and the first and the second metal gate layers 252, 254 can include a high work function metal gate selected from the group consisting of tantalum cabonitride, tungsten, tungsten nitride, molybdenum nitride, ruthenium, and ruthenium oxide, wherein the first transistor device 202 over the first active region 212 can include a PMOS device and the second transistor device 204 over the second active region 214 can include an NMOS device. In some other embodiments, the first dielectric capping layer 232 can include an oxide layer selected from the group consisting of lanthanum oxide, yttrium oxide, gadolinium oxide, cerium oxide, dysprosium oxide, ytterbium oxide, terbium oxide, erbium oxide, and scandium oxide; and the first and second metal gate layers 252, 254 can include a high work function metal gate selected from the group consisting of tantalum cabonitride, tungsten, tungsten nitride, molybdenum nitride, ruthenium, and ruthenium oxide, wherein the first transistor device 202 in the first active region 212 can include an NMOS device and the second transistor device 204 in the second active region 214 can include a PMOS device.

According to various embodiments, there is a CMOS device 100 as shown in FIG. 1K. The CMOS device 100 can include a substrate 110 including a first active region 112, a second active region 114, and a trench isolation region 116. The CMOS device 100 can also include a first transistor device 102 over the first active region 112, wherein the first transistor device 102 can include a high-K layer 120 over the first active region 112, a first dielectric capping layer 132 on the high-K layer 120, and a first metal gate layer 152 on the first dielectric capping layer 132. The CMOS device 100 can further include a second transistor device 104 over the second active region 114, wherein the second transistor device 104 can include a high-K layer 120 over the second active region 114, a second dielectric capping layer 134 on the high-K layer 120, and a second metal gate layer 154 on the second dielectric capping layer 134. In some embodiments, the first metal gate layer 152 including tantalum nitride can be positioned over the first dielectric capping layer 132 including aluminum nitride to form a p-type device (work function of 5.0 eV). In other embodiments, the second metal gate layer 154 including tantalum nitride can be positioned over the second dielectric capping layer 132 including lanthanum oxide to form an n-type device (work function of 4.0 eV).

Thus, the methods of making CMOS devices according to present teachings use a single metal rather than two for both the n-type and p-type devices. Furthermore, the use of high quality high-K layer can prevent charges at the first and second dielectric capping layers from migrating downwards towards the channel, thereby increasing reliability.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.”

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of making a CMOS device comprising:
providing a substrate comprising a first active region and a second active region;
forming a high-K layer over the first active region and the second active region;
forming a first dielectric capping layer disposed on the high-K layer over the first active region;
forming a second dielectric capping layer disposed on the high-K layer over the second active region;
forming a metal gate layer over the first dielectric capping layer and the second dielectric capping layer; and
patterning the high-K layer, the first and the second dielectric capping layers and the metal gate layer to form a first transistor device over the first active region and a second transistor device over the second active region.

2. The method of claim 1, wherein the step of forming a high-K layer over the first active region and the second active region comprises forming one or more of a silicon oxide layer, a plasma nitrided oxide layer, a hafnium based dielectric layer, and a zirconium based dielectric layer.

3. The method of claim 1, wherein the step of forming a first dielectric capping layer disposed on the high-K layer over the first active region comprises forming an aluminum-containing dielectric layer comprising one or more of aluminum nitride, aluminum oxide, and aluminum oxynitride.

4. The method of claim 1, wherein the step of forming a second dielectric capping layer disposed on the high-K layer over the second active region comprises forming an oxide layer selected from the group consisting of lanthanum oxide, yttrium oxide, gadolinium oxide, cerium oxide, dysprosium oxide, ytterbium oxide, terbium oxide, erbium oxide, and scandium oxide.

5. The method of claim 1, wherein the step of forming a metal gate layer over the first dielectric capping layer and the second dielectric capping layer comprises forming a midgap metal gate layer comprising one or more of tantalum nitride, zirconium nitride, and titanium nitride.

6. A method of making an integrated circuit comprising:
providing a substrate comprising a first active region and a second active region;
forming a high-K layer over the first active region and the second active region;
forming a first dielectric capping layer on the high-K layer over the first active region;
forming a metal gate layer on the first dielectric capping layer over the first active region and on the high-K layer over the second active region; and
patterning the high-K layer, the first dielectric capping layer, and the metal gate layer to form a first transistor device over the first active region and patterning the high-K layer and the metal gate layer to form a second transistor device over the second active region.

7. The method of claim 6, wherein the step of forming a high-K layer over the first active region and the second active region comprises forming one or more of a silicon oxide layer, a plasma nitrided oxide layer, a hafnium based dielectric layer, and a zirconium based dielectric layer.

8. The method of claim 6, wherein the step of forming a first dielectric capping layer on the high-K layer over the first active region comprises forming an oxide layer selected from the group consisting of lanthanum oxide, yttrium oxide, gadolinium oxide, cerium oxide, dysprosium oxide, ytterbium oxide, terbium oxide, erbium oxide, and scandium oxide.

9. The method of claim 6, wherein the step of forming a first dielectric capping layer on the high-K layer over the first active region comprises forming an aluminum-containing dielectric layer comprising one or more of aluminum nitride, aluminum oxide, and aluminum oxynitride.

10. The method of claim 6, wherein the step of forming a metal gate layer on the first dielectric capping layer over the first active region and the high-K layer over the second active region comprises forming a high work function metal gate selected from the group consisting of tantalum cabonitride, tungsten, tungsten nitride, molybdenum nitride, ruthenium, and ruthenium oxide.

11. A semiconductor device comprising:
a substrate comprising a first active region and a second active region;
a first transistor device over the first active region, wherein the first transistor device comprises a high-K layer over the first active region, a first dielectric capping layer on the high-K layer, and a first metal gate layer on the first dielectric capping layer; and
a second transistor device over the second active region, wherein the second transistor device comprises a high-K layer over the second active region and a second metal gate layer on the high-K layer.

12. The semiconductor device of claim 11, wherein the high-K layer comprises one or more of a silicon oxide layer, a plasma nitrided oxide layer, a hafnium based dielectric layer, and a zirconium based dielectric layer.

13. The semiconductor device of claim 11, wherein the first dielectric capping layer comprises an aluminum-containing dielectric layer comprising one or more of aluminum nitride, aluminum oxide, and aluminum oxynitride.

14. The semiconductor device of claim 11, wherein the first metal gate layer and the second metal gate layer comprise a high work function metal gate selected from the group consisting of tantalum cabonitride, tungsten, tungsten nitride, molybdenum nitride, ruthenium, and ruthenium oxide.

15. The semiconductor device of claim 13, wherein the first transistor device in the first active region comprises a PMOS device and the second transistor device in the second active region comprises an NMOS device.

16. The semiconductor device of claim 11, wherein the first dielectric capping layer in the first active region comprises an oxide layer selected from the group consisting of lanthanum oxide, yttrium oxide, gadolinium oxide, cerium oxide, dysprosium oxide, ytterbium oxide, terbium oxide, erbium oxide, and scandium oxide.

17. The semiconductor device of claim 16, wherein the first transistor device in the first active region comprises an NMOS device and the second transistor device in the second active region is a CMOS device.

18. A CMOS device comprising:
a substrate comprising a first active region and a second active region;
a first transistor device over the first active region, wherein the first transistor device comprises a high-K layer over the first active region, a first dielectric capping layer disposed on the high-K layer, and a first metal gate layer over the first dielectric capping layer; and
a second transistor device over the second active region, wherein the second transistor device comprises a high-K layer over the second active region, a second dielectric capping layer disposed on the second high-K layer, and a second metal gate layer over the second dielectric capping layer.

19. The CMOS device of claim 18, wherein the high-K layer comprises one or more of a silicon oxide layer, a plasma nitrided oxide layer, a hafnium based dielectric layer, and a zirconium based dielectric layer.

20. The CMOS device of claim 18, wherein the first dielectric capping layer comprises an aluminum-containing dielectric layer comprising one or more of aluminum nitride, aluminum oxide, and aluminum oxynitride.

21. The CMOS device of claim 18, wherein the second dielectric capping layer comprises an oxide layer selected from the group consisting of lanthanum oxide, yttrium oxide, gadolinium oxide, cerium oxide, dysprosium oxide, ytterbium oxide, terbium oxide, erbium oxide, and scandium oxide.

22. The CMOS device of claim 18, wherein the first metal gate layer and the second metal gate layer comprise a midgap metal gate comprising one or more of tantalum nitride, zirconium nitride, and titanium nitride.
